(19) United States
(12) Patent Application Publication
(10) Pub. No.: US 2026/0040458 A1
(43) Pub. Date: Feb. 5, 2026

(54) THIN, STRETCHABLE AND FLEXIBLE PRINTED CIRCUIT AND MANUFACTURING METHOD THEREFOR

(71) Applicant: MFLEX (YANCHENG) CO., LTD., YANCHENG (CN)

(72) Inventors: JIE ZHANG, YANCHENG (CN); ZONGMIN HU, YANCHENG (CN); JIANCHENG CAO, YANCHENG (CN)

(73) Assignee: MFLEX (YANCHENG) CO., LTD., YANCHENG (CN)

(21) Appl. No.: 19/027,657

(22) Filed: Jan. 17, 2025

Related U.S. Application Data
(63) Continuation of application No. PCT/CN2024/108710, filed on Jul. 31, 2024.

(51) Int. Cl. H05K 3/00; H05K 1/02; H05K 1/03

(52) U.S. Cl. CPC H05K 3/007; H05K 1/0277; H05K 1/0393; H05K 3/0044; H05K 2201/05; H05K 2201/09009; H05K 2203/0147; H05K 2203/0228; H05K 2203/10; H05K 2203/1194; H05K 2203/1377

(57) ABSTRACT

Disclosed are a thin, stretchable and flexible printed circuit and a manufacturing method therefor. The manufacturing method comprise: attaching an adhesion-reducing carrier film to a first side of a flexible circuit board provided with a circuit layer and two protective films, wherein the adhesion-reducing carrier film has a large first preset adhesive force; and attaching a first elastomer composite film, and then performing an adhesion-reducing operation on the adhesion-reducing carrier film to allow the adhesion-reducing carrier film to have a small second preset adhesive force. The elastomer composite film is formed by two polymer films with different melting points. The invention can increase the product yield in mass production based on the adhesion-reducing carrier film and can wrap a serpentine circuit by means of the elasticity of a composite structure of the polymer films to realize thin and light design and miniaturization.

### TECHNICAL FIELD

The invention relates to the field of manufacturing of flexible printed circuits, in particular to a thin, stretchable and flexible printed circuit and a manufacturing method therefor.

### BACKGROUND

Flexible and stretchable electronics, as an emerging technology, are developed and widely applied because they are compressible and distortable and can fit complex non-planar surfaces. At present, the application of wearable electronics exerts a positive influence on all aspects in daily life and promotes the growth of economy and rapid development of stretchable electronic equipment and related manufacturing techniques. Flexible, soft and stretchable electronic equipment makes it possible for the application of the next generation of wearable electronics and creates various applications in the healthcare field, the energy field and the military field.

Stretchable conductor circuits, as an important part of flexible and stretchable electronics, not only can guarantee the stretchability of the flexible and stretchable electronics, but also can function for signal transmission and power transmission. At present, there are many methods for manufacturing stretchable conductor circuits. Wherein, a mainstream method comprises: manufacturing a bendable and stretchable serpentine circuit with metal wires such copper wires or aluminum wires, and then wrapping the serpentine circuit in a high-elasticity polymer (also referred to as an elastomer). By adopting such a method, first, the serpentine circuit needs to be manufactured on a carrier film; then, the carrier film needs to be stripped after the serpentine circuit and the elastomer are combined. To guarantee the product yield in mass production, before the serpentine circuit and the elastomer are combined, the binding force between the carrier film and the serpentine circuit should be large enough to ensure that the serpentine circuit will not be separated from the carrier film when an undesired scrap area is discharged (stripped); and after the serpentine circuit and the elastomer are combined, the binding force between the carrier film and the serpentine circuit should be small enough to ensure that the carrier film can be stripped while the serpentine circuit will not be separated from the elastomer. However, such a mass production method is difficult to implement and leads to a low product yield in mass production.

In addition, the serpentine circuit and the elastomer are combined at present generally by casting, which requires the design of a complex mold; a stretchable conductor circuit manufactured in this way has a large thickness (generally greater than 1 mm), which is not beneficial for thin and light design and miniaturization of flexible and stretchable electronics.

### SUMMARY

In view of this, the invention provides a thin, stretchable and flexible printed circuit and a manufacturing method therefor to solve the problems that the yield of existing stretchable printed circuits in mass production is low and the large thickness of circuits is not beneficial for thin and light design and miniaturization of products.

The invention provides a manufacturing method for a thin, stretchable and flexible printed circuit, comprising:
a step of providing a flexible circuit board provided with a circuit layer and two protective films, and attaching an adhesion-reducing carrier film to a first side of the flexible circuit board to form a first circuit board, wherein the two protective layers are located on two sides of the circuit layer respectively, and the adhesion-reducing carrier film has a first preset adhesive force;
a step of performing contour cutting, from a second side of the first circuit board, on the two protective films in the first circuit board to form a serpentine circuit by the circuit layer and the two protective films subjected to the contour cutting, and stripping scrap from the cut first circuit board to form a second circuit board, wherein the serpentine circuit has at least one stretching direction;
a step of providing a first elastomer composite film, attaching the first elastomer composite film to a second side of the second circuit board, and performing an adhesion-reducing operation on the adhesion-reducing carrier film on a first side of the second circuit board to allow the adhesion-reducing carrier film to have a second preset adhesive force to form a third circuit board, wherein the second preset adhesive force is less than the first preset adhesive force; and a step of stripping the adhesion-reducing carrier film from the third circuit board to form a target circuit.

Optionally, the adhesion-reducing carrier film is any one of a UV adhesion-reducing film and a thermal adhesion-reducing film.

Optionally, in a case where the adhesion-reducing carrier film is the UV adhesion-reducing film, performing an adhesion-reducing operation on the adhesion-reducing carrier film on a first side of the second circuit board comprises:
performing UV exposure on the adhesion-reducing carrier film on the first side of the second circuit board;
in a case where adhesion-reducing carrier film is the thermal adhesion-reducing film, performing an adhesion-reducing operation on the adhesion-reducing carrier film on a first side of the second circuit board comprises:
heating the adhesion-reducing carrier film on the first side of the second circuit board.

Optionally, the first preset adhesive force is greater than 500 gf/inch, and the second preset adhesive force is less than 100 gf/inch.

Optionally, the first elastomer composite film comprises a first polymer film with a first melting point and a second polymer film with a second melting point, and the second polymer film is arranged on a side of the first polymer film; wherein, the first melting point is lower than the second melting point.

Optionally, the step of providing a first elastomer composite film, attaching the first elastomer composite film to a second side of the second circuit board, and performing an adhesion-reducing operation on the adhesion-reducing carrier film on a first side of the second circuit board to allow the adhesion-reducing carrier film to have a second preset adhesive force to form a third circuit board comprises:
performing the adhesion-reducing operation on the adhesion-reducing carrier film on the first side of the second circuit board to allow the adhesion-reducing carrier film to have the second preset adhesive force;
providing the first elastomer composite film; and
attaching a side, provided with the first polymer film, of the first elastomer composite film to the second side of the second circuit board subjected to the adhesion-reducing operation to form the third circuit board.

Optionally, the step of providing a first elastomer composite film, attaching the first elastomer composite film to the second side of the second circuit board, and performing an adhesion-reducing operation on the adhesion-reducing carrier film on a first side of the second circuit board to allow the adhesion-reducing carrier film to have a second preset adhesive force to form a third circuit board comprises:
providing the first elastomer composite film;
attaching a side, provided with the first polymer film, of the first elastomer composite film to the second side of the second circuit board; and
performing the adhesion-reducing operation on the adhesion-reducing carrier film on the first side of the second circuit board to allow the adhesion-reducing carrier film to have the second preset adhesive force to form the third circuit board.

Optionally, after the step of stripping the adhesion-reducing carrier film from the third circuit board, the manufacturing method further comprises:
a step of providing a second elastomer composite film identical with the first elastomer composite film; and
a step of attaching a side, provided with the first polymer film, of the second elastomer composite film to a first side of the third circuit board formed after the adhesion-reducing carrier film is stripped.

Optionally, a difference between the second melting point and the first melting point ranges from 20° C. to 100° C.

Optionally, a difference between the second melting point and the first melting point ranges from 30° C. to 60° C.

Optionally, a thickness of the first polymer film ranges from 30 μm to 100 μm, and/or, a thickness of the second polymer film ranges from 25 μm to 150 μm.

Optionally, the serpentine circuit comprises:
a substrate layer;
at least one wire layer, laminated on one or two sides of the substrate layer; and
the two protective films subjected to the contour cutting, respectively adhered to outermost wire layers or the substrate layer by means of adhesive layers.

Optionally, one or more wires are configured in each wire layer.

In addition, the invention further provides a thin, stretchable and flexible printed circuit, which is manufactured by the manufacturing method described above.

The invention has the following beneficial effects: because when the serpentine circuit is formed by the circuit layer and the two protective films, on one hand, the two protective films need to be cut to form a stretchable serpentine circuit by the circuit layer; on the other hand, because the first elastomer composite film needs to be attached to the serpentine circuit, the adhesion-reducing carrier film is attached to the first side of the flexible circuit board provided with the circuit layer and the two protective films, and when the serpentine circuit is formed, the adhesion-reducing carrier film can function as a carrier film to support the whole first circuit board during cutting to facilitate manufacturing of the serpentine circuit; when scrap is stripped and the first elastomer composite film is attached later, the adhesion-reducing carrier film functions as a support to form the thin, stretchable and flexible printed circuit; the adhesion-reducing carrier film has an adhesion reduction effect, that is, the adhesion-reducing carrier film can reduce the adhesion (the adhesive force can be reduced) by a certain adhesion-reducing operation, such that when the scrap is stripped after the serpentine circuit is manufactured, a large binding force between the serpentine circuit and the adhesion-reducing carrier film can be guaranteed based on a large adhesive force before the adhesion-reducing operation, thus ensuring that the serpentine circuit will not be separated from the adhesion-reducing carrier film when the scrap is stripped; after the first elastomer composite film is attached, the adhesive force is reduced by the adhesion-reducing operation, thus ensuring that the adhesion-reducing carrier film can be easily stripped while the serpentine circuit will not be separated from the first elastomer composite film. In this way, mass production of stretchable and flexible printed circuits can be realized, and the yield of mass production is increased. In addition, because the first elastomer composite film is a composite structure with multiple polymer films, it not only can wrap the serpentine circuit by means of the elasticity of the polymer films, but also can adapt to different lamination processes by means of the characteristics of different polymer films, thus reducing the thickness of the stretchable and flexible printed circuits and realizing thin and light design and miniaturization of flexible and stretchable electronics.

### BRIEF DESCRIPTION OF THE DRAWINGS

The features and advantages of the invention will be better understood with reference to the accompanying drawings. The drawings are used to illustrate some embodiments of the invention and should not be construed as any limitations of the invention. Wherein:

FIG. 1 illustrates a flow diagram of a manufacturing method for a thin, stretchable and flexible printed circuit according to Embodiment 1 of the invention;

FIG. 2A and FIG. 2B respectively illustrate sectional views of a first circuit board before and after contour cutting according to Embodiment 1 of the invention;

FIG. 3 illustrates a cross-sectional view of a serpentine circuit according to Embodiment 1 of the invention;

FIG. 4 illustrates a schematic diagram of a U-shaped serpentine circuit according to Embedment 1 of the invention;

FIG. 5 illustrates a schematic diagram of a horseshoe-shaped serpentine circuit according to the Embodiment 1 of the invention;

FIG. 6 illustrates a top view of a circuit layer after the serpentine circuit is manufactured according to Embodiment 1 of the invention;

FIG. 7 illustrates a sectional view of a first elastomer composite film according to Embedment 1 of the invention;

FIG. 8 illustrates a front view of a target circuit according to Embodiment 2 of the invention;

FIG. 9 illustrates a sectional view of the target circuit according to Embodiment 1 of the invention.

### REFERENCE SIGNS

1, flexible board; 2, first elastomer composite film; 3, second elastomer composite film; 11, serpentine circuit; 12, transition area; 13, non-stretchable area; 111, substrate layer; 112, wire layer; 113, protective film; 114, adhesive layer; 21, first polymer film; 22, second polymer film; 4, adhesion-reducing carrier film.

### DETAILED DESCRIPTION OF PREFERRED EMBODIMENTS

To gain a better understanding of the purposes, technical solutions and advantages of the embodiments of the invention, the technical solutions in the embodiments of the invention are clearly and completely described below conjunction with the accompanying drawings of these embodiments. Obviously, the embodiments in the following description are merely illustrative ones, and are not all possible ones, all other embodiments obtained by those skilled in the art according to the following ones without creative labor should also fall within the protection scope of the invention.

### Embodiment 1

This embodiment provides a manufacturing method for a thin, stretchable and flexible printed circuit. As shown in FIG. 1, the manufacturing method comprises:
S1: providing a flexible circuit board provided with a circuit layer and two protective films, and attaching an adhesion-reducing carrier film to a first side of the flexible circuit board to form a first circuit board, wherein the two protective layers are located on two sides of the circuit layer respectively, and the adhesion-reducing carrier film has a first preset adhesive force;
S2, cutting, from a second side of the first circuit board, the two protective films in the first circuit board to form a serpentine circuit by the circuit layer and the two cut protective films, and stripping scrap from the cut first circuit board to form a second circuit board, wherein the serpentine circuit has at least one stretching direction;
S3, providing a first elastomer composite film, attaching the first elastomer composite film to a second side of the second circuit board, and performing an adhesion-reducing operation on the adhesion-reducing carrier film on a first side of the second circuit board to allow the adhesion-reducing carrier film to have a second preset adhesive force to form a third circuit board, wherein the second preset adhesive force is less than the first preset adhesive force; and
S4: stripping the adhesion-reducing carrier film from the third circuit board to form a target circuit.

In this embodiment, because when the serpentine circuit is formed by the circuit layer and the two protective films, on one hand, the two protective films need to be cut to form a stretchable serpentine circuit by the circuit layer; on the other hand, because the first elastomer composite film needs to be attached to the serpentine circuit, the adhesion-reducing carrier film is attached to the first side of the flexible circuit board provided with the circuit layer and the two protective films, and when the serpentine circuit is formed, the adhesion-reducing carrier film can function as a carrier film to support the whole first circuit board during cutting to facilitate manufacturing of the serpentine circuit; when scrap is stripped and the first elastomer composite film is attached later, the adhesion-reducing carrier film functions as a support to form the thin, stretchable and flexible printed circuit; the adhesion-reducing carrier film has a adhesion reduction effect, that is, the adhesion-reducing carrier film can reduce the adhesion (the adhesive force can be reduced) by a certain adhesion-reducing operation, such that when the scrap is stripped after the serpentine circuit is manufactured, a large binding force between the serpentine circuit and the adhesion-reducing carrier film can be guaranteed based on a large adhesive force before the adhesion-reducing operation, thus ensuring that the serpentine circuit will not be separated from the adhesion-reducing carrier film when the scrap is stripped; after the first elastomer composite film is attached, the adhesive force is reduced by the adhesion-reducing operation, thus ensuring the adhesion-reducing carrier film can be easily stripped while the serpentine circuit will not be separated from the first elastomer composite film. In this way, mass production of stretchable and flexible printed circuits can be realized, and the yield of mass production is increased. In addition, because the first elastomer composite film is a composite structure with multiple polymer films, it not only can wrap the serpentine circuit by means of the elasticity of the polymer films, but also can adapt to different lamination processes by means of the characteristics of different polymer films, thus reducing the thickness of the stretchable and flexible printed circuits and realizing thin and light design and miniaturization of flexible and stretchable electronics.

Each step of the manufacturing method for a thin, stretchable and flexible printed circuit is described in detail below.

In this embodiment, in S1, the flexible circuit board provided with the circuit layer and the two protective films is a printed circuit obtained by a DES process, including developing and exposure of a dry film, etching, stripping, chemical cleaning, attachment of protective films, lamination, and the like. In this way, the circuit layer, in conformity with the product design, is formed on the flexible circuit board, and the protective films are attached to two sides of the circuit layer.

In this embodiment, in S1, the adhesion-reducing carrier film is mainly prepared from a polyester (PET) film and a special acrylic adhesive, has good adhesion and protective performance, and can reduce the adhesive force and frictional force under a certain condition to fulfill a specific purpose. In this embodiment, the adhesion-reducing carrier film, which is generally applied to wafer cutting, is used as a carrier film for manufacturing a thin, stretchable and flexible printed circuit; on one hand, the adhesion-reducing carrier film fulfills a support effect for contour cutting of the protective films, and on the other hand, when scraps is stripped after the serpentine circuit is manufactured, the adhesion-reducing carrier film guarantees a large binding force between the serpentine circuit and the adhesion-reducing carrier film to ensure that the serpentine circuit will not be separated from the adhesion-reducing carrier film when the scrap is stripped; after the first elastomer composite film is attached, because the adhesive force is reduced by the adhesion-reducing operation, the adhesion-reducing carrier film can be easily stripped while the serpentine circuit will not be separated from the first elastomer composite film, such that the problem that it is difficult to realize mass production of flexible and stretchable electronics in the prior art is solved, and the yield of mass production is increased.

It should be noted that the circuit layer in this embodiment comprises the serpentine circuit (which may be formed by a conventional method and will not be repeated here). Because the whole protective films are attached to the circuit layer in the actual process, the serpentine circuit cannot stretch and is not a real stretchable serpentine circuit, so contour cutting needs to be performed on the protective films later to make the serpentine circuit stretchable along curves.

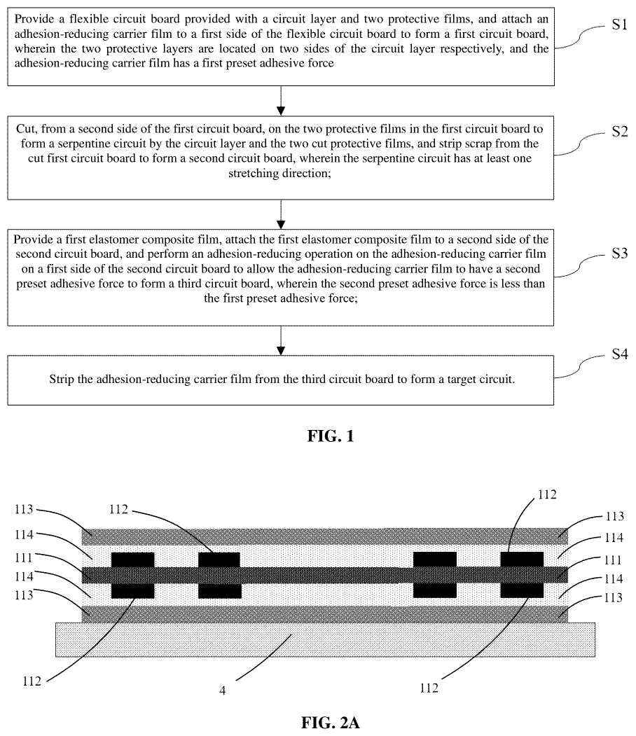

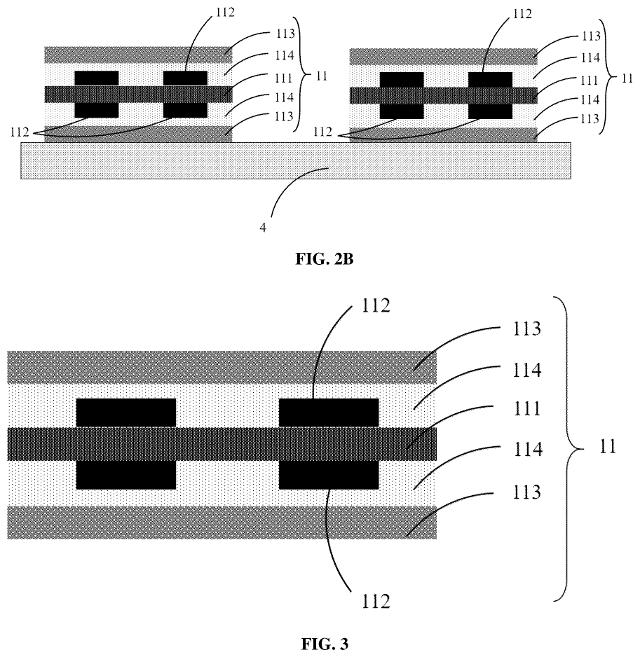

In this embodiment, before contour cutting in S2, the sectional structure of the first circuit board is shown in FIG. 2A. In this embodiment, the contour cutting in S2 may be implemented by various methods, such as pattern cutting with laser and punching by means of a mold with a specific pattern. No matter which method is adopted, the protective films at the curves of the circuit need to be cut without affecting the adhesion-reducing carrier film, so as to guarantee the completeness and continuity of the adhesion-reducing carrier film. After contour cutting, the sectional structure of the first circuit board is shown in FIG. 2B. In FIGS. 2A and 2B, 111 is a substrate layer, 112 is a wire layer, 113 is a protective film, 114 is an adhesive layer, and 4 is an adhesion-reducing carrier film.

Preferably, as shown in FIGS. 2B and 3-5, in this embodiment, the serpentine circuit 11 manufactured in S2 comprises:
a substrate layer 111;
at least one wire layer 112, formed on one or two sides of the substrate layer 111; and
two protective films 1113 subjected to contour cutting, respectively adhered to outermost wire layers 112 or the substrate layer 111 by means of adhesive layers 114.

The serpentine circuit of the above structure has good stretchability and circuit protection performance, can guarantee the functionality of a whole stretchable and flexible printed circuit, and can prevent metal in the circuit layer against cracks, fractures and other problems that may affect the functionality, thus prolonging the service life of the stretchable and flexible printed circuit.

Specifically, the substrate layer 111 is made from one or a mixture of several of polyimide (PI), polyethylene terephthalate (PET), LCP and polybutylene terephthalate (PBT). Wherein, the LCP is a liquid crystal polymer, comprising polybenzene terephthalate (PBT), polymethyl methacrylate (PMMA), polycarbonate (PC), etc.

The wire layer 112 is a metal wire layer and made from copper or aluminum.

The protective films 113 are also made from one or a mixture of several of polyimide (PI), polyethylene terephthalate (PET), LCP, polybutylene terephthalate (PBT), and used for protecting the wire layer and the substrate layer in the serpentine circuit.

The adhesive layers 114 are made from one or a mixture of several of epoxy resin, acrylic resin and polyolefin resin.

In the serpentine circuit, one, two or more wire layers are configured. In a case where one wire layer is configured, the wire layer is formed on only one side of the substrate layer. In a case where two or more wire layers are configured, the wire layers may be formed on one side or two sides of the substrate layer (generally on two sides).

In the serpentine circuit, two protective films are configured and respectively adhered to outermost layers of the serpentine circuit by means of the adhesive layers (at least two adhesive layers should be configured). Wherein, in a case where the wire layer is distributed on only one side of the substrate layer, one of the two protective films is adhered to the outermost wire layer by means of one adhesive layer, and the other one of the two protective films is adhered to the outermost substrate layer by means of the other adhesive layer. In a case where the wire layers are distributed on two sides of the substrate layer, one of the two protective films is adhered to the outmost wire layer on the first side of the serpentine circuit by means of one adhesive layer, and the other one of the two protective films is adhered to the outermost wire layer on the second side of the serpentine circuit by means of the other adhesive layer.

In the serpentine circuit, on or more wires are configured in each wire layer.

The use of one or more wires can adapt to the design of different flexible and stretchable electronics.

Wherein, the number of the wire layers and the number of wires in each wire layer depend on specific product design and are not limited here.

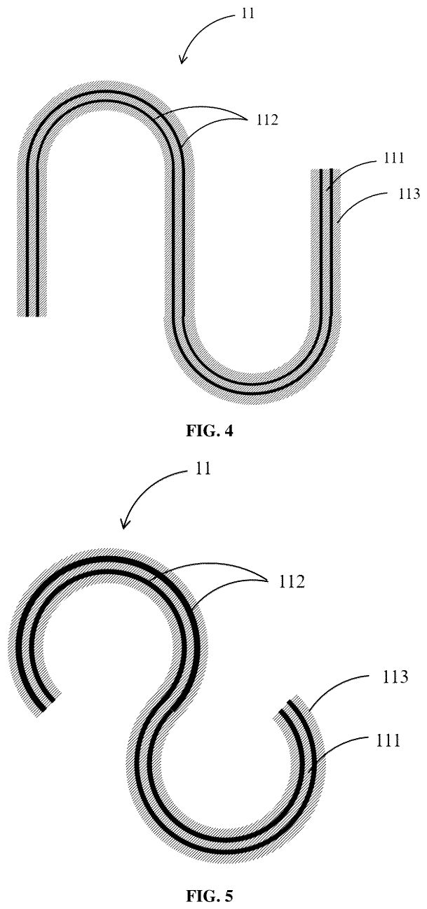

In this embodiment, the serpentine circuit 11 shown in FIGS. 2B and 3-5 comprises a substrate layer 111, two wire layers 112, two protective films 113 subjected to contour cutting, and two adhesive layers 114, wherein the two wire layers 112 are located on two sides of the substrate layer 111 respectively, and the two protective films 113 subjected to contour cutting are adhered to outer sides of the wire layers 112 by means of the adhesive layers 114 respectively, such that a double-layer circuit structure is formed. Wherein, in FIG. 4, the serpentine circuit is U-shaped; in FIG. 5, the serpentine circuit is horseshoe-shaped (the two adhesive layers 114 are not shown in FIGS. 4 and 5). Two wires are configured in each wire layer.

In this embodiment, one or more serpentine circuits may be configured.

The use of different numbers of serpentine circuits may also adapt to the design of different flexible and stretchable electronics. The specific number and shape of the serpentine circuit depend on specific product design and are not limited here.

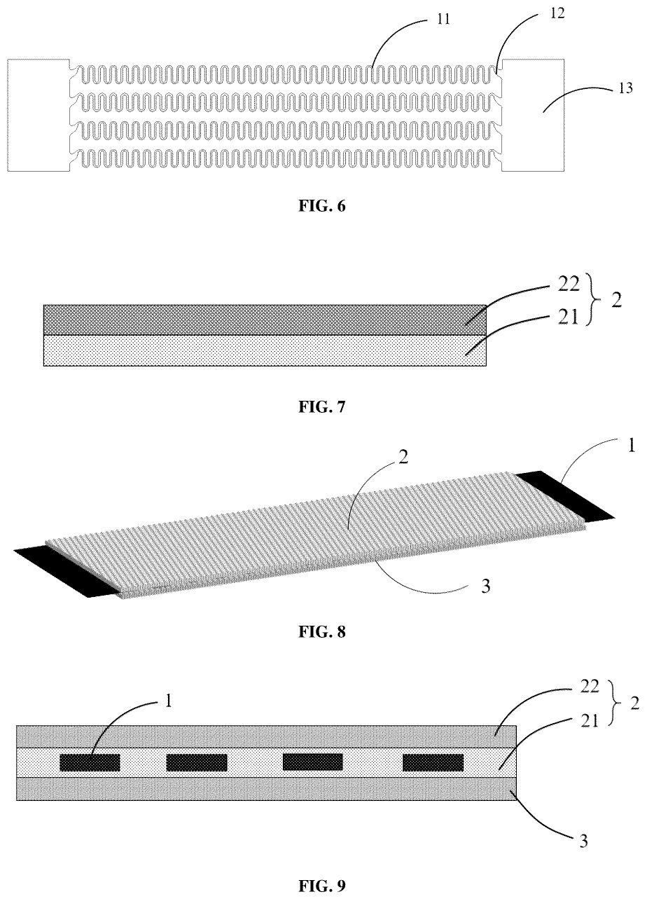

In this embodiment, in S2, the serpentine circuit 11 is a stretchable area of the circuit layer. When the circuit layer is made into the serpentine circuit 11, and the circuit layer on the first circuit board further comprises transition areas 12 connected to two ends of the serpentine circuit 11 and non-stretchable areas 13 respectively connected to the transition areas 12 at the two ends, as shown in FIG. 6 (wherein, four serpentine circuits 11 are shown in FIG. 6). The transition areas 12 are formed by circuit board structures which become thicker gradually, and such circuit board structures allow for a gradual change of stress during stretching and thus are unlikely to be fractured. The non-stretchable areas 13 are formed by circuit board structures with a fixed size, and when the non-stretchable areas 13 are stretched, the size of the non-stretchable areas 13 will not change. According to actual conditions, components that have certain functions or components that have different functions and are connected to different serpentine circuits may be arranged in the non-stretchable areas 13. In FIG. 6, four transition areas 12 at each end are connected to the same non-stretchable area 13.

Preferably, in this embodiment, in S3, as shown in FIG. 7, the first elastomer composite film 2 comprises a first polymer film 21 with a first melting point and a second polymer film 22 with a second melting point, and the second polymer film 22 is arranged on one side of the first polymer film 21; wherein, the first melting point is lower than the second melting point.

The first elastomer composite film formed by the first polymer film with a low melting point (the first melting point) and the second polymer film with a high melting point (the second melting point) not only has good elasticity to wrap the serpentine circuit, but also can adapt to different lamination processes by means of the characteristics of different polymer films; when laminated, the first polymer film with the low melting point will flow to bond together the whole first elastomer composite film and a flexible substrate (to be exact, the second circuit board) and reduce the thickness of the whole elastomer composite film to facilitate miniaturization and thin and light design of flexible electronics; when laminated, the second polymer film with the high melting point will not flow, such that the strength of the first elastomer composite film is guaranteed on the promise that the elasticity of the first elastomer composite film is guaranteed, thus protecting flexible electronics.

In a first optimal embodiment, S3 comprises:
S3A1: performing the adhesion-reducing operation on the adhesion-reducing carrier film on the first side of the second circuit board to allow the adhesion-reducing carrier film to have the second preset adhesive force;
S3A2: providing the first elastomer composite film; and
S3A3: attaching a side, provided with the first polymer film, of the first elastomer composite film to the second side of the second circuit board subjected to the adhesion-reducing operation to form the third circuit board.

In the above optional embodiment, first, the adhesion-reducing operation is performed, and then the first elastomer composite film is attached to form the third circuit board. In this way, the adhesive force of the adhesion-reducing carrier film is reduced by means of the adhesion-reducing operation, such that when the adhesion-reducing carrier film is stripped after the third circuit board is formed, the adhesion-reducing carrier film can be easily stripped, and the serpentine circuit will not be separated from the first elastomer composite film; the side, provided with the first polymer film, of the first elastomer composite film is attached to the second side of the second circuit board as an inner layer, such that the adhesion-reducing carrier film can be used as a carrier film to facilitate attachment and can also be easily stripped later; by means of the low melting point of the first polymer film, the whole first elastomer composite film and the flexible board (to be exact, the second circuit board) are bonded together to warp the serpentine circuit.

In a second optional embodiment, S3 comprises:
S3B1: providing the first elastomer composite film;
S3B2: attaching a side, provided with the first polymer film, of the first elastomer composite film to the second side of the second circuit board; and
S3B3: performing the adhesion-reducing operation on the adhesion-reducing carrier film on the first side of the second circuit board to form the third circuit board.

In the second optional embodiment, first, the first elastomer composite film is attached, and then the adhesion-reducing operation is performed to obtain the third circuit board. Identical with the first optional embodiment, the adhesive force of the adhesion-reducing carrier film can be reduced by means of the adhesion-reducing operation, such that the adhesion-reducing carrier film can be easily stripped while the serpentine circuit will not be separated from the first elastomer composite film; the side, provided with the first polymer film, of the first elastomer composite film is attached to the second side of the second circuit board as an inner layer, attachment is facilitated, and the adhesion-reducing carrier film can be easily stripped later; the whole first elastomer composite film and the flexible board (to be exact, the second circuit board) are bonded together to warp the serpentine circuit.

In addition, compared with the first optional embodiment, the second optional embodiment can prevent the situation that the flexible board is separated from the adhesion-reducing carrier film after the adhesion-reducing operation due to movement or transfer of the flexible board and can also prevent negative influences caused by reaction between an adhesive on the adhesion-reducing carrier film and the first elastomer composite film during the adhesion-reducing operation, thus further improving the yield of flexible and stretchable electronics in mass production.

Of course, if the flexible board will not be separated from the adhesion-reducing carrier film due to movement or transfer after the adhesion-reducing operation and the adhesive on the adhesion-reducing carrier film will not react with the first elastomer composite film during the adhesion-reducing operation, the first optional embodiment or the second optimal embodiment may be selected to form the third circuit board according to the actual condition.

Preferably, the adhesion-reducing carrier film is any one of a UV adhesion-reducing film and a thermal adhesion-reducing film.

Preferably, in a case where the adhesion-reducing carrier film is the UV adhesion-reducing film, in S3, performing an adhesion-reducing operation on the adhesion-reducing carrier film on a first side of the second circuit board comprises:
performing UV exposure on the adhesion-reducing carrier film on the first side of the second circuit board;
in a case where adhesion-reducing carrier film is the thermal adhesion-reducing film, in S3, performing an adhesion-reducing operation on the adhesion-reducing carrier film on a first side of the second circuit board comprises:
heating the adhesion-reducing carrier film on the first side of the second circuit board.

Both the UV adhesion-reducing film and the thermal adhesion-reducing film have good adhesion and protective performance and can reduce the adhesive force by means of a simple adhesion-reducing operation (including UV exposure and heating) to reduce the difficulty of mass production of flexible and stretchable electronics.

Preferably, the first preset adhesive force is greater than 500 gf/inch, and the second preset adhesive force is less than 100 gf/inch.

The large first preset adhesive force within the above range ensures a large binding force between the serpentine circuit and the adhesion-reducing carrier film when scrap is stripped after the serpentine circuit is manufactured, such that the serpentine circuit will not be separated from the adhesion-reducing carrier film when the scrap is stripped. The small second preset adhesive force within the above range ensures that the adhesion-reducing carrier film can be easily stripped and the serpentine circuit will not be separated from the first elastomer composite film after the first elastomer composite film is attached, thus realizing mass production of stretchable and flexible printed circuits and increasing the yield of the stretchable and flexible printed circuits in mass production.

Suitable adhesion-reducing films may be selected as the UV adhesion-reducing film and the thermal adhesion-reducing film according to the actual condition. For example, the UV adhesion-reducing film may be an SL-9715UV-3 UV adhesion-reducing film, and the thermal adhesion-reducing film may be an SL-9900J adhesion-reducing film.

In this embodiment, the adhesion-reducing carrier film and the first elastomer composite film may be attached by a conventional attachment method, and the scrape and the adhesion-reducing carrier film may be stripped by a conventional stripping method. Specific details of attachment and stripping operations will not be repeated here.

Preferably, in S4, after the step of stripping the adhesion-reducing carrier film from the third circuit board, the method further comprises:
a step of providing a second elastomer composite film identical with the first elastomer composite film; and
a step of attaching a side, provided with the first polymer film, of the second elastomer composite film to a first side of the third circuit board formed after the adhesion-reducing carrier film is stripped.

By attaching the second elastomer composite film identical with the first elastomer composite film to the first side of the third circuit board after the adhesion-reducing carrier film is stripped, both sides of the whole third circuit board can be wrapped, thus further protecting the serpentine circuit and improving the product quality.

The specific method for attaching the second elastomer composite film is the same as the specific method for attaching the first elastomer composite film, and specific details will not be repeated here.

Preferably, in the first elastomer composite film and the second elastomer composite film, a difference between the second melting point and the first melting point ranges from 20° C. to 100° C.

Preferably, a difference between the second melting point and the first melting point ranges from 30° C. to 60° C.

The difference between the melting points can better adapt to different lamination processes; when laminated, the first polymer film with a low melting point will flow to bond together the whole first elastomer composite film and the flexible board (to be exact, the second circuit board) and facilitate miniaturization and thin and light design of flexible electronics; when laminated, the second polymer film with a high melting point will not flow, such that the strength of the first elastomer composite film is guaranteed on the promise that the elasticity of the first elastomer composite film is guaranteed.

Preferably, in the first elastomer composite film and the second elastomer composite film, the thickness of the first polymer film ranges from 30 μm to 100 μm, and/or, the thickness of the second polymer film ranges from 25 μm to 150 μm.

The characteristics of the first polymer film and the second polymer film with the above thicknesses can be given into full play, and the thickness of the first elastomer composite film and the thickness of the second elastomer composite film can be minimized, thus facilitating thin and light design and miniaturization of flexible and stretchable electronics.

Preferably, in the first elastomer composite film and the second elastomer composite film, the tensile modulus of the first polymer film and the tensile modulus of the second polymer film are both less than 10 MPa; and/or, the elongation at break of the first polymer film and the elongation at break of the second polymer film are both greater than or equal to 200%.

The above tensile modulus and elongation at break can effectively guarantee the good stretchability of the whole target circuit.

In an optional embodiment, the first polymer film and the second polymer film are made from one or more of modified copolymers including a polyester copolymer, a polyimide copolymer, a polyamide copolymer, a polyolefin copolymer, a polycarbonate copolymer and a polyacrylonitrile-butene-styrene copolymer.

The first polymer film and the second polymer film made from the above materials can restore after being stretched, and different from novel conductor materials such as conducting polymers, conductor particle and elastomer composite materials, and liquid metals (alloys containing gallium and indium), the conductivity will not be reduced with the increase of the tensile elongation; and the stretchability of the first polymer film and the second polymer film is stable, which is beneficial for the manufacturing of flexible and stretchable electronics with good stretchability.

Preferably, after the second elastomer composite film is attached, the manufacturing method further comprises:
a step of baking the third circuit board attached with the second elastomer composite film.

By baking, the first polymer films with a low melting point in the first elastomer composite film and the second elastomer composite film can be further cured to improve the binding force between the first elastomer composite film and the flexible board and the binding force between the second elastomer composite film and the flexible board.

As shown in FIG. 8 which illustrates a front view of the target circuit finally manufactured in this embodiment and FIG. 9 which illustrates a sectional view of the target circuit, the target circuit comprises a flexible board 1 with the serpentine circuit 11, and the first elastomer composite film 2 and the second elastomer composite film 3 which are located on two sides of the flexible board 1.

It should be understood that in the actual manufacturing process, because the target circuits are manufactured in batches, the flexible board 1 in FIG. 9 is provided with multiple serpentine circuits (to be specific, four); when the second elastomer composite film 3 is laminated on the third circuit board, the first polymer film in the second elastomer composite film 3 will flow to be fused with the first polymer film in the first elastomer composite film 2 and the first polymer film in the second elastomer composite film 3 on an adjacent flexible board, so the first polymer film 21 in FIG. 9 is actually an integrated structure of the first polymer film in the first elastomer composite film 2 and the first polymer film in the second elastomer composite film 3.

To further explain this scheme, four examples are provided, and samples of the target circuit in this scheme are manufactured in the four examples (the sectional view of which is shown in FIG. 8), and the maximum elongations and tensile cycles of the samples are compared.

The cross-section of the serpentine circuit 11 in the sample manufactured in Example 1 is shown in FIG. 4, the first polymer films in the first elastomer composite film and the second elastomer composite film are polyurethane (TPU) films, the corresponding first melting point is 100° C., the tensile modulus is 0.4 MPa, and the thickness is 60 μm; the second polymer films in the first elastomer composite film and the second elastomer composite film are also TPU films, the corresponding second melting point is 150° C., the tensile modulus is 4 MPa, and the thickness is 60 μm.

The cross-section of the serpentine circuit 11 in the sample manufactured in Example 2 is shown in FIG. 5, the first polymer films and the second polymer films in the first elastomer composite film and the second elastomer composite film are the same as those in Example 1 and will not be detailed anymore here.

The cross-section of the serpentine circuit 11 in the sample manufactured in Example 3 is shown in FIG. 4, the first polymer films in the first elastomer composite film and the second elastomer composite film are polydimethylsiloxane (PDMS) films, the corresponding first melting point is 120° C., the tensile modulus is 0.1 MPa, and the thickness is 60 μm; the second polymer films in the first elastomer composite film and the second elastomer composite film are also PDMS films, the corresponding second melting point is 150° C., the tensile modulus is 0.4 MPa, and the thickness is 100 μm.

The cross-section of the serpentine circuit 11 in the sample manufactured in Example 4 is shown in FIG. 5, the first polymer films and the second polymer films in the first elastomer composite film and the second elastomer composite film are the same as those in Example 3 and will not be detailed anymore here.

After the samples in the examples are manufactured, the maximum elongation and tensile cycles of the samples are evaluated and compared. Wherein, an evaluation method is as follows:

An evaluation process of the maximum elongation is as follows:
(1) The length L₀ of the stretchable area of the sample is measured, the non-stretchable areas at the two ends of the sample are clamped on clamps of a tensile machine to maintain the natural form of the sample;
(2) The sample is stretched at a velocity of 500 mm/min until the sample is fractured, and at this moment, the length of the stretchable area is L; and
(3) The maximum elongation of the sample is calculated by a formula: L/L₀×100%.

An evaluation process of the tensile cycles is as follows:
(1) The length L₀ of the stretchable area of the sample is measured, the non-stretchable areas at the two ends of the sample are clamped on clamps of a tensile machine to maintain the natural form of the sample;
(2) Resistance test electrodes are connected to two ends of the serpentine circuit to test whether the metal wire in the serpentine circuit is short-circuited; and
(3) The sample is stretched cyclically, and every time the sample is stretched, the stretchable area of the sample is stretched by a length of 100% and is stretched for 45 times per minute until the sample is destroyed by a test or the wire is short-circuited.

The maximum elongations and tensile cycles of the samples in the example are evaluated according to the above evacuation method and compared in Table 1.

TABLE 1
Maximum elongation and tensile cycles
of samples in four examples

| | Example 1 | Example 2 | Example 3 | Example 4 |
|---|---|---|---|---|
| Maximum elongation | 224 | 234 | 176 | 188 |
| Tensile cycles | 2000 | 2000 | 3000 | 3000 |

It can be known, from the above comparison results, that the thin, stretchable and flexible printed circuit manufactured by the manufacturing method in this scheme has good stretchability.

### Embodiment 2

This embodiment provides a thin, stretchable and flexible printed circuit, which is manufactured by the manufacturing method in Embodiment 1.

Compared with traditional stretchable printed circuits, the thin, stretchable and flexible printed circuit manufactured in this embodiment can reduce the difficulty of mass production and increase the product yield in mass production based on an adhesion-reducing carrier film; a composite structure based on polymer films can wrap a serpentine circuit by means of its elasticity and adapt to different lamination processes to reduce the thickness of the stretchable and flexible printed circuit, thus realizing thin and light design and miniaturization of flexible and stretchable electronics

The steps of a manufacturing method adopted for the thin, stretchable and flexible printed circuit in this embodiment are the same as the steps of the manufacturing method in Embodiment 1, so details that are not given in this embodiment may be understood with reference to specific descriptions of FIGS. 1-9 in Embodiment 1 and will not be repeated here.

Although the embodiments of the invention are described in conjunction with the accompanying drawings, those skilled in the art can make various modifications and transformations without departing from the spirit and scope of the invention, and all these modifications and transformations should also fall within the scope defined by the appended claims.

1. A manufacturing method for a thin, stretchable and flexible printed circuit, comprising:
a step of providing a flexible circuit board provided with a circuit layer and two protective films, and attaching an adhesion-reducing carrier film to a first side of the flexible circuit board to form a first circuit board, wherein the two protective layers are located on two sides of the circuit layer respectively, and the adhesion-reducing carrier film has a first preset adhesive force;
a step of performing contour cutting, from a second side of the first circuit board, on the two protective films in the first circuit board to form a serpentine circuit by the circuit layer and the two protective films subjected to the contour cutting, and stripping scrap from the cut first circuit board to form a second circuit board, wherein the serpentine circuit has at least one stretching direction;
a step of providing a first elastomer composite film, attaching the first elastomer composite film to a second side of the second circuit board, and performing an adhesion-reducing operation on the adhesion-reducing carrier film on a first side of the second circuit board to allow the adhesion-reducing carrier film to have a second preset adhesive force to form a third circuit board, wherein the second preset adhesive force is less than the first preset adhesive force; and
a step of stripping the adhesion-reducing carrier film from the third circuit board to form a target circuit.

2. The manufacturing method according to claim 1, wherein the adhesion-reducing carrier film is any one of a UV adhesion-reducing film and a thermal adhesion-reducing film.

3. The manufacturing method according to claim 2, wherein in a case where the adhesion-reducing carrier film is the UV adhesion-reducing film, performing an adhesion-reducing operation on the adhesion-reducing carrier film on a first side of the second circuit board comprises:
performing UV exposure on the adhesion-reducing carrier film on the first side of the second circuit board;
in a case where adhesion-reducing carrier film is the thermal adhesion-reducing film, performing an adhesion-reducing operation on the adhesion-reducing carrier film on a first side of the second circuit board comprises:
heating the adhesion-reducing carrier film on the first side of the second circuit board.

4. The manufacturing method according to claim 1, wherein the first preset adhesive force is greater than 500 gf/inch, and the second preset adhesive force is less than 100 gf/inch.

5. The manufacturing method according to claim 1, wherein the first elastomer composite film comprises a first polymer film with a first melting point and a second polymer film with a second melting point, and the second polymer film is arranged on a side of the first polymer film; wherein, the first melting point is lower than the second melting point.

6. The manufacturing method according to claim 5, wherein the step of providing a first elastomer composite film, attaching the first elastomer composite film to a second side of the second circuit board, and performing an adhesion-reducing operation on the adhesion-reducing carrier film on a first side of the second circuit board to allow the adhesion-reducing carrier film to have a second preset adhesive force to form a third circuit board comprises:
performing the adhesion-reducing operation on the adhesion-reducing carrier film on the first side of the second circuit board to allow the adhesion-reducing carrier film to have the second preset adhesive force;
providing the first elastomer composite film; and
attaching a side, provided with the first polymer film, of the first elastomer composite film to the second side of the second circuit board subjected to the adhesion-reducing operation to form the third circuit board.

7. The manufacturing method according to claim 5, wherein the step of providing a first elastomer composite film, attaching the first elastomer composite film to a second side of the second circuit board, and performing an adhesion-reducing operation on the adhesion-reducing carrier film on a first side of the second circuit board to allow the adhesion-reducing carrier film to have a second preset adhesive force to form a third circuit board comprises:
providing the first elastomer composite film;
attaching a side, provided with the first polymer film, of the first elastomer composite film to the second side of the second circuit board; and
performing the adhesion-reducing operation on the adhesion-reducing carrier film on the first side of the second circuit board to allow the adhesion-reducing carrier film to have the second preset adhesive force to form the third circuit board.

8. The manufacturing method according to claim 5, wherein after the step of stripping the adhesion-reducing carrier film from the third circuit board, the manufacturing method further comprises:
a step of providing a second elastomer composite film identical with the first elastomer composite film; and
a step of attaching a side, provided with the first polymer film, of the second elastomer composite film to a first side of the third circuit board formed after the adhesion-reducing carrier film is stripped.

9. The manufacturing method according to claim 5, wherein a difference between the second melting point and the first melting point ranges from 20° C. to 100° C.

10. The manufacturing method according to claim 5, wherein a difference between the second melting point and the first melting point ranges from 30° C. to 60° C.

11. The manufacturing method according to claim 5, wherein a thickness of the first polymer film ranges from 30 μm to 100 μm, and/or, a thickness of the second polymer film ranges from 25 μm to 150 μm.

12. The manufacturing method according to claim 1, wherein the serpentine circuit comprises:
a substrate layer;
at least one wire layer, laminated on one or two sides of the substrate layer; and
the two protective films subjected to the contour cutting, respectively adhered to outermost said wire layers or the substrate layer by means of adhesive layers.

13. The manufacturing method according to claim 12, wherein one or more wires are configured in each said wire layer.

14. A thin, stretchable and flexible printed circuit, being manufactured by the manufacturing method according to any one of claims 1-13.
